(19) United States
(12) Patent Application Publication
(10) Pub. No.: US 2014/0224425 A1
(43) Pub. Date: Aug. 14, 2014

(54) FILM THICKNESS MONITORING METHOD, FILM THICKNESS MONITORING DEVICE, AND SEMICONDUCTOR MANUFACTURING APPARATUS

(71) Applicant: KABUSHIKI KAISHA TOSHIBA, Minato-ku (JP)

(72) Inventor: Toru MIKAMI, Yokkaichi-Shi (JP)

(73) Assignee: KABUSHIKI KAISHA TOSHIBA, Minato-ku (JP)

(21) Appl. No.: 14/021,340

(22) Filed: Sep. 9, 2013

Related U.S. Application Data
(60) Provisional application No. 61/764,007, filed on Feb. 13, 2013.

(51) Int. Cl. H01L 21/66; H01L 21/67

(52) U.S. Cl. CPC H01L 22/12; H01L 21/67011; H01L 21/67075
USPC 156/345.13; 356/630; 118/712

(57) ABSTRACT

In accordance with an embodiment, a film thickness monitoring method includes applying light to a substrate, which is a processing target, in a semiconductor manufacturing process involving rotation of the substrate, detecting reflected light from the substrate, and calculating a thickness of a film on the substrate. The thickness of the film is calculated from intensity of the reflected light detected in an identified time zone in which incident light passes a desired region on the substrate during the semiconductor manufacturing process.

### CROSS REFERENCE TO RELATED APPLICATIONS

This application is based upon and claims the benefit of U.S. provisional Application No. 61/764,007, filed on Feb. 13, 2013, the entire contents of which are incorporated herein by reference.

### FIELD

Embodiments relate to a film thickness monitoring method, a film thickness monitoring device, and a semiconductor manufacturing apparatus.

### BACKGROUND

In manufacturing a semiconductor device, various kinds of materials are repeatedly formed into films on a wafer, to form a laminated structure. To form this laminated structure, a film of a resist material must be formed on the wafer, and it is also necessary to flatten a surface of the uppermost layer in the formed laminated structure by chemical mechanical polishing (which will be simply referred to as “CMP” hereinafter). In such a case, to form a resist film which is just enough, or to perform polishing to be neither too much nor too little, a film thickness must be accurately measured.

### BRIEF DESCRIPTION OF THE DRAWINGS

In the accompanying drawings:

FIG. 1 is a view showing an outline configuration of a semiconductor manufacturing apparatus according to Embodiment 1;

FIG. 2 is a schematic view showing a detailed configuration of a film thickness monitoring device included in the semiconductor manufacturing apparatus depicted in FIG. 1;

FIG. 3 is a view for explaining a relationship between an example of the laminated structure on a wafer and an optical path of the film thickness monitoring device depicted in FIG. 2;

FIG. 4A and FIG. 4B are views for explaining a film thickness monitoring method according to Example 1;

FIG. 5 is a view sowing an example of a distribution of signal intensity obtained in a specified passage time zone alone;

FIGS. 6A and 6B and FIG. 7 are views each showing an example of a distribution of signal intensity according to a reference example;

FIG. 8 is a view for explaining a film thickness monitoring method according to Example 2; and

FIG. 9 is a view showing an outline configuration of a semiconductor manufacturing apparatus according to Embodiment 2.

### DETAILED DESCRIPTION

In accordance with an embodiment, a film thickness monitoring method includes applying light to a substrate, which is a processing target, in a semiconductor manufacturing process involving rotation of the substrate, detecting reflected light from the substrate, and calculating a thickness of a film on the substrate. The thickness of the film is calculated from intensity of the reflected light detected in an identified time zone in which incident light passes a desired region on the substrate during the semiconductor manufacturing process.

Embodiments will now be explained with reference to the accompanying drawings. Like components are provided with like reference signs throughout the drawings and repeated descriptions thereof are appropriately omitted.

(A) Semiconductor Manufacturing Apparatus according to

### Embodiment 1

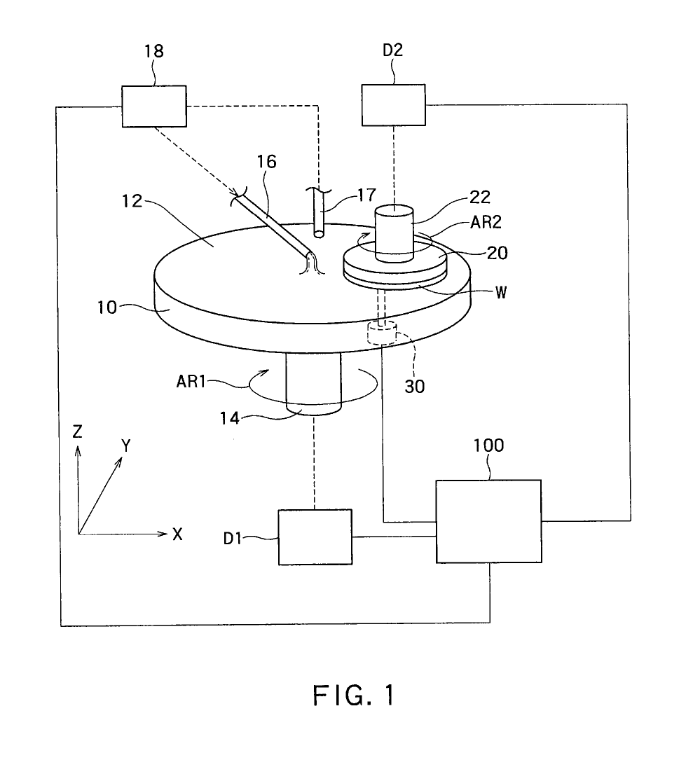

FIG. 1 is a view showing an outline configuration of a semiconductor manufacturing apparatus according to Embodiment 1. The semiconductor manufacturing apparatus shown in FIG. 1 is a polishing apparatus including a polishing table 10, a polishing pad 12, a polishing table shaft 14, nozzles 16 and 17, a liquid supply control mechanism 18, a top ring 20, a top ring shaft 22, a control section 100, and a film thickness monitoring device 30.

The polishing table 10 is coupled with the polishing table shaft 14 and supports the polishing pad 12 on an upper surface thereof. The polishing table 10 rotates in a rotating direction indicated by, e.g., a reference sign AR1 in FIG. 1 when the polishing table shaft 14 rotates by a drive mechanism D1 including a motor (not shown) and others. In this embodiment, the polishing table 10 corresponds to, e.g., a second table 2.

The top ring 20 is coupled with the top ring shaft 22 and presses a wafer W against the polishing pad 12 while holding the wafer W in such a manner that the surface of the polishing target faces the polishing pad 12. The top ring 20 rotates in, e.g., a rotating direction AR2 when the top ring shaft 22 rotates by a drive mechanism D2 including a motor (not shown) and others. In this embodiment, the top ring 20 corresponds to, e.g., a first table.

It is to be noted that each of the polishing table shaft 14, the polishing table 10, the top ring shaft 22, and the top ring 20 can not only rotate but also move in three-dimensional arbitrary directions, i.e., all of an X direction, a Y direction, and a Z direction in FIG. 1, thereby enabling scanning by the film thickness monitoring device 30 based on an arbitrary procedure.

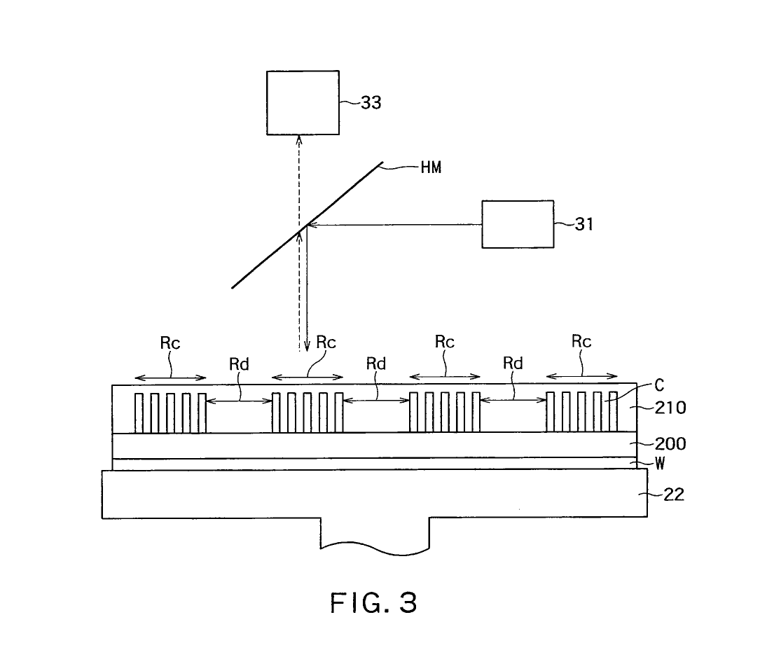

During polishing, the polishing table 20 rotates while slurry is supplied onto the polishing pad 12 by the liquid supply control mechanism 18 through the nozzle 16, and the top ring 20 rotates while pressing the wafer W against the polishing pad 12, whereby the polishing target surface of the wafer W is polished by relative rotation of the polishing pad 12 and the wafer W. In this embodiment, the wafer W is, e.g., a silicon wafer having memory cells C formed in memory cell regions Rc on an upper surface thereof through a semiconductor layer 200 and having an interlayer insulating film 210 formed on the entire surface thereof, and the interlayer insulating film 210 is a polishing target (see FIG. 3)

In this embodiment, the wafer W corresponds to, e.g., a substrate. It is needless to say that the substrate is not restricted to the silicon wafer and, for example, a glass substrate is also included.

The film thickness monitoring device 30 in FIG. 1 measures a thickness of a polishing target during polishing, calculates a polishing amount, and supplies data of the calculated polishing amount to the control section 100.

The control section 100 generates respective control signals, supplies them to the respective drive mechanisms D1 and D2, the liquid supply control mechanism 18, and the film thickness monitoring device 30, and controls a general polishing process while monitoring a polishing amount based on the data of the film thickness supplied from the film thickness monitoring device 30. When a film thickness value calculated by the film thickness monitoring device 30 reaches a desired value, the control section 100 terminates the polishing process.

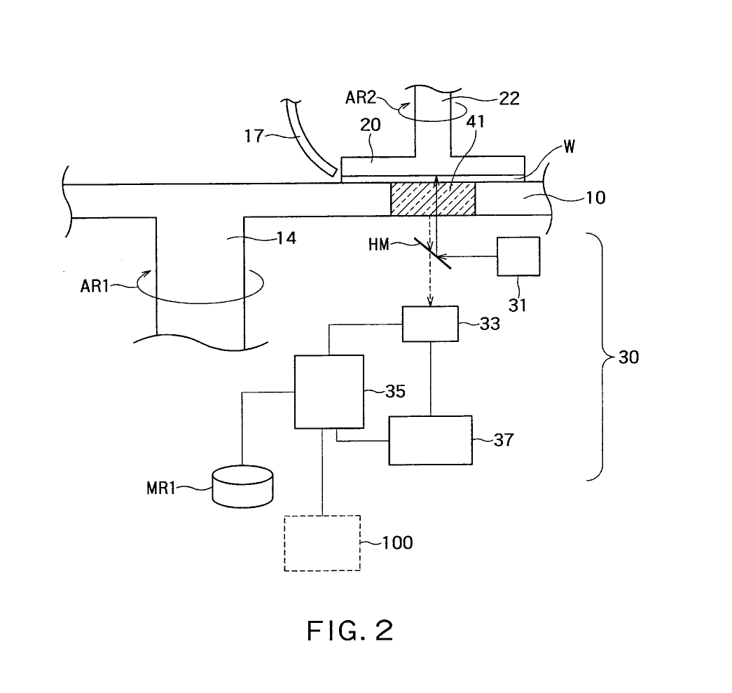

FIG. 2 is a schematic view showing a more detailed configuration of the film thickness monitoring device 30. Further, FIG. 3 is a view for explaining a relationship between an example of a laminated structure on the wafer W and an optical path of the film thickness monitoring device shown in FIG. 2. In FIG. 3, for ease of explanation, the polishing table 10 in FIG. 2 is omitted, and the top and bottom (a vertical relationship) in FIG. 2 are reversed and shown.

The film thickness monitoring device 30 includes a light emitter 31, a half mirror HM, a light detector 33, and a passage time identifying section 35, and a film thickness calculating section 37. The passage time identifying section 35 is connected to a memory MR1. The memory MR1 stores data concerning a design shot layout of a device formed on the wafer W, which is a memory device in this embodiment, and design data of the polishing apparatus itself. The layout data and the design data will be described later.

The light emitter 31 includes, e.g., a halogen light source, emits visible light of approximately 400 nm to approximately 800 nm, and applies it to the half mirror HM. The visible light, which has been reflected on the half mirror HM to change its optical path, illuminates the polishing target surface of the wafer W. The light detector 33 detects the reflected light from the polishing target surface and outputs a signal indicative of reflection intensity of the reflected light. In this embodiment, the light emitter 31 corresponds to, e.g., a light irradiating section, and the light detector 33 corresponds to, e.g., a detecting section.

The passage time identifying section 35 receives the signal from the light detector 33 and carries out later-described passage time identification processing before or concurrently with the polishing process.

The film thickness calculating section 37 processes the signal resulting from the reflected light detected in a passage time zone identified by the passage time identifying section 35 and calculates a polishing amount of the interlayer insulating film 210 in FIG. 3.

In this embodiment, in the polishing table 10, a measurement window 41 made of a transparent material having higher hardness than a polishing material, e.g., quartz glass is provided for each of a portion which emitted light from the half mirror HM illuminates and a portion through which the reflected light from the polishing target surface of the wafer W passes. Other portions of the polishing table 10 are made of, e.g., stainless so that they can cope with pressure from the polishing table shaft 14.

During the polishing, since interposition of the slurry between the wafer W and each measurement window 41 is a problem, the slurry is washed out by spraying pure water from the liquid supply control mechanism 18 in FIG. 1 through the nozzle 17, and then air is injected through the nozzle 17 for removal of the pure water so that the air alone can be present between the wafer W and each measurement window 41. As a result, a film thickness of the polishing surface can be measured without removing the semiconductor substrate W from the top ring 20.

It is to be noted that the configuration for assuring optical paths of the incident light and the reflected light through the polishing table 10 is not restricted to the example in FIG. 2 at all. For example, an optical transmission hole may be formed in a portion corresponding to each measurement window 41 in FIG. 2 in place of the transparent material, and an optical fiber may be inserted into this hole in such a manner that the incident light can be allowed to pass, and a liquid such as pure water may be supplied or discharged into or from the hole, thereby avoiding scattering of the reflected light.

An operation of the film thickness monitoring device 30 will now be described as an example of a film thickness monitoring method with reference to FIG. 3 to FIG. 9.

### (1) Example 1

In the example shown in FIG. 3, the interlayer insulating film 210 as a polishing target is formed to cover memory devices formed in an array shape at predetermined intervals on the semiconductor layer 200 on the wafer W. In such an example, a polishing amount relative to the interlayer insulating film 210 becomes a problem in each memory cell region Rc where the memory device is formed, each dicing region Rd between the memory cell regions Rc is diced in a later packaging process, and hence a polishing amount in each dicing region Rd itself is not a problem.

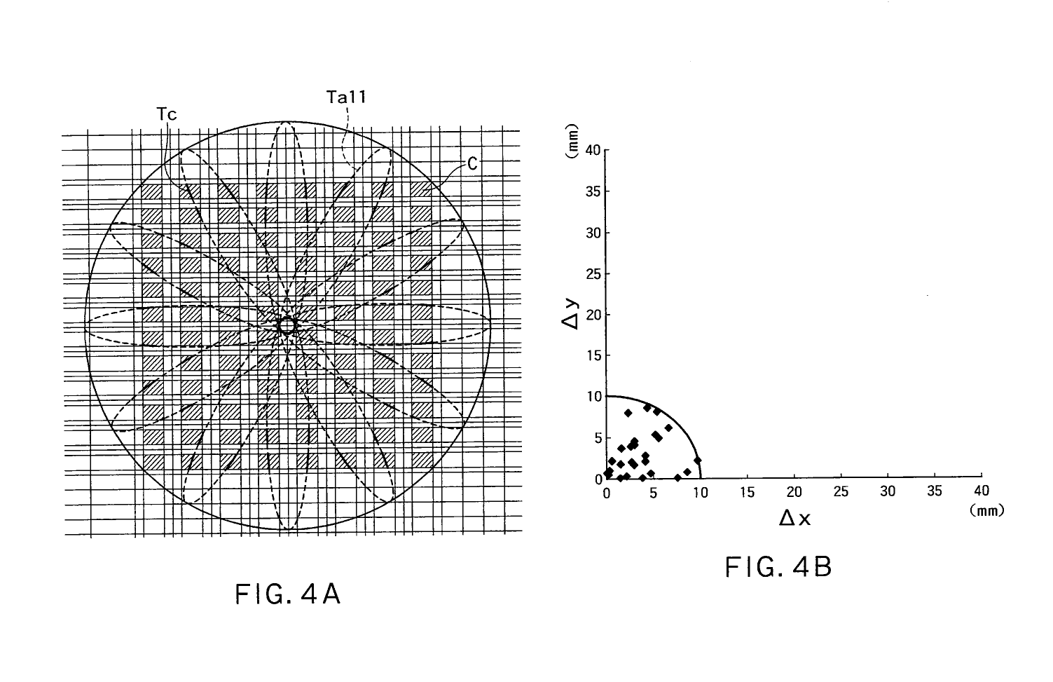

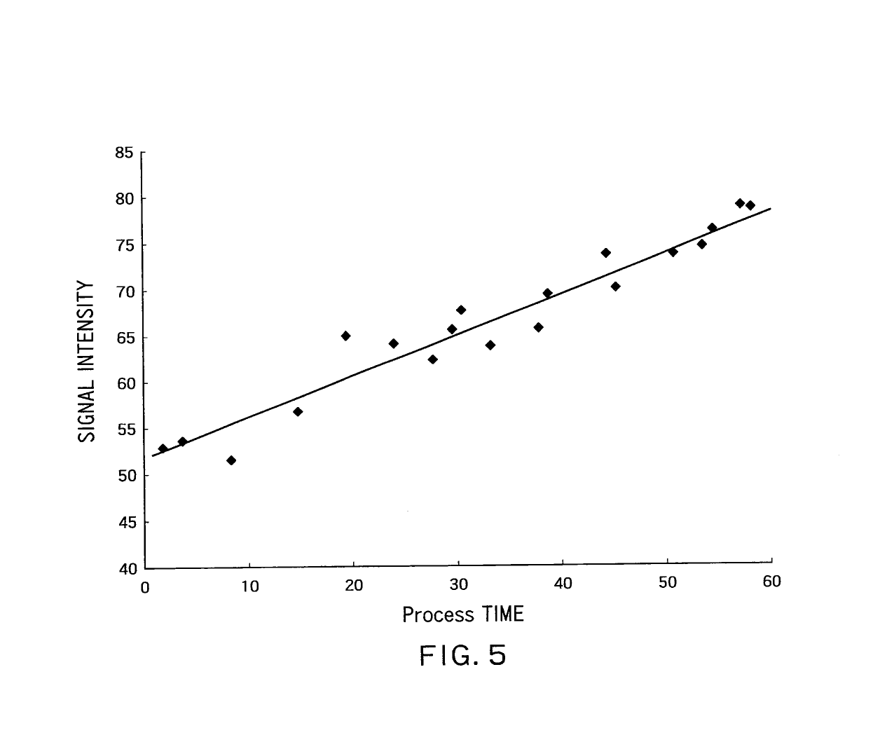

Thus, in this example, a region within a predetermined distance from the center of each memory cell is defined as a region of interest ROI, the passage time identifying section 35 identifies a time zone in which the film thickness monitoring device 30 passes the ROI during the polishing process, and the film thickness calculating section 37 in FIG. 2 calculates a thickness of the interlayer insulating film 210 in FIG. 3 from intensity of reflected light detected in the identified time zone. This point will now be described with reference to FIG. 4A to FIG. 5.

FIG. 4A is a view showing trajectories of the film thickness monitoring device 30 on the wafer W when the polishing pad 12 and the wafer W in FIG. 1 relatively rotate during the polishing process. A trajectory Tall indicated by a dotted line in FIG. 4A represents a trajectory of the film thickness monitoring device 30 when continuous scan is simply performed. On the other hand, a trajectory Tc indicated by a solid line in FIG. 4A represents a trajectory that the film thickness monitoring device 30 passes ROI in the trajectory Tall.

FIG. 4B is a view showing an example of plotting an intensity distribution of reflected light detected on the trajectory Tc onto an X-Y coordinate having the center of the memory cell C as an origin. A predetermined distance from the center of the memory cell C is, e.g., a distance that is a half of a short side of the memory cell C, and a region that is, e.g., 10 mm from the center of each memory cell C is determined as the ROI in this example. The ROI corresponds to, e.g., a desired region in this example. It is to be noted that the region ROI is not restricted to the region within a fixed distance from the center of the memory cell C as long as it is a region on the memory cell C, and it may be, e.g., a rectangular region according to a shape of the memory cell C.

Such a reflected light intensity distribution can be obtained by allowing the emitted light to illuminate the interlayer insulating film 210 in FIG. 3 and detecting reflected light at predetermined time intervals in a time zone in which the film thickness monitoring device 30 passes the ROI, which is identified by the passage time identifying section 35 in FIG. 2.

The ROI passage time zone is identified by the passage time identifying section 35 in FIG. 2 based on (i) a method of performing continuous scan prior to the polishing process or (ii) a method using design data of the manufacturing apparatus.

(i) Method of Performing Continuous Scan in Advance

Monitoring scan prior to the polishing process can be effected by polishing (water polishing) which is carried out while watering, e.g., the polishing pad 12 in FIG. 1.

First, the control section 100 generates control signals, supplies them to the drive mechanisms D1 and D2 and the liquid supply control mechanism 18, drives the polishing table shaft 14 and the top ring shaft 22 by using these drive mechanisms D1 and D2, respectively, pure water or the like is jetted through the nozzle 17, and the polishing table 10 and the top ring 20 relatively rotate, whereby performing the water polishing. Respective non-illustrated encoders are disposed to the drive mechanisms D1 and D2, and values of the respective encoders (not shown) are supplied to the control section 100 during the water polishing.

The passage time identifying section 35 in FIG. 2 includes a non-illustrated timer, converts a value supplied from each encoder (not shown) through the control section 100 into an wafer radial X-Y coordinate, and associates this value with time data supplied from the timer, thereby creating estimated trajectory data for estimating the trajectory Tall of the film thickness monitoring device 30.

The passage time identifying section 35 further fetches layout data concerning a design shot layout of each memory device formed on the wafer W from the memory MR1, compares an X-Y coordinate of the estimated trajectory data with the layout data, and estimates a time zone in which the film thickness monitoring device 30 passes the ROI.

(ii) Method Using Design Data of Manufacturing Apparatus

Since there is design data such as a polishing procedure in regard to the polishing apparatus itself, this data can be stored in the memory MR1 in advance, and it can be fetched from the memory MR1 before polishing or concurrently with the polishing process, thus estimating an ROI passage time zone.

Specifically, the passage time identifying section 35 fetches the design data of the polishing apparatus from the memory MR1, creates the estimated trajectory data for estimating the trajectory Tall of the film thickness monitoring device 30, compares an X-Y coordinate of this data with the layout data, and thereby estimates a time zone in which the film thickness monitoring device 30 passes the ROI.

When polishing the wafer W begins under control of the control section 100 in FIG. 1, the film thickness monitoring device 30 allows light to illuminate the polishing target surface of the wafer W by using the light emitter 31 in accordance with data of the passage time zone estimated by the passage time identifying section 35 in FIG. 2, detects reflected light by using the light detector 33, outputs a signal indicative of reflection intensity of the reflected light, and calculates a film thickness of the interlayer insulating film 210 in FIG. 3 by using the film thickness calculating section 37.

FIG. 5 shows an example of a distribution of the signal intensity of the reflected light detected only in the passage time zone estimated by the passage time identifying section 35 in FIG. 2. It can be understood from FIG. 5 that the signal intensity tends to gradually increase with advancement of the polishing process.

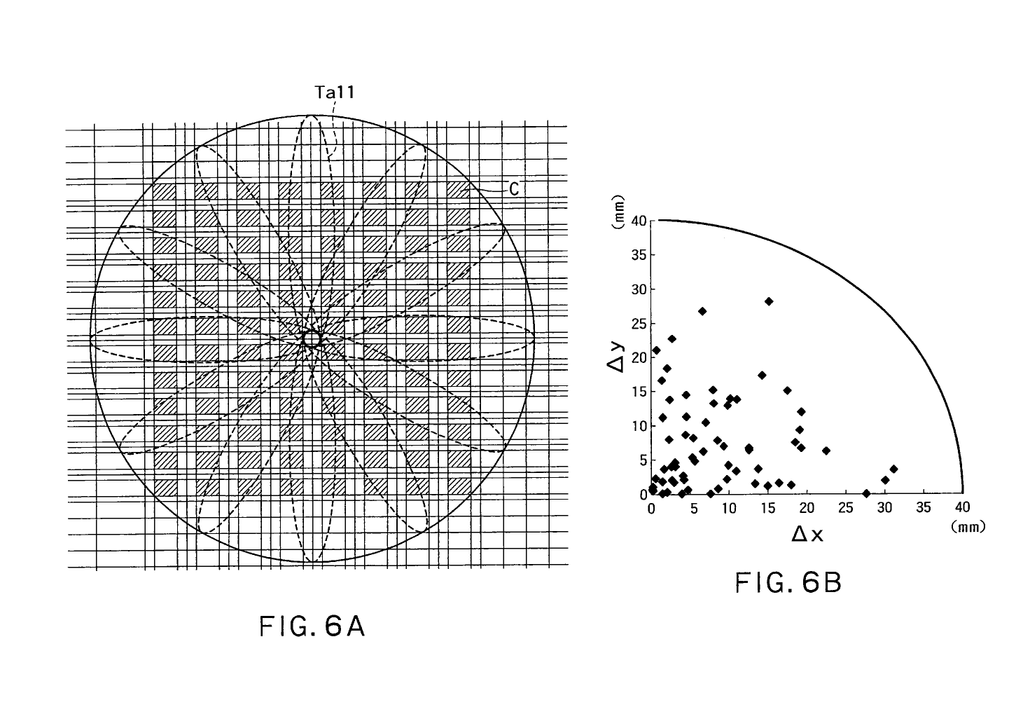

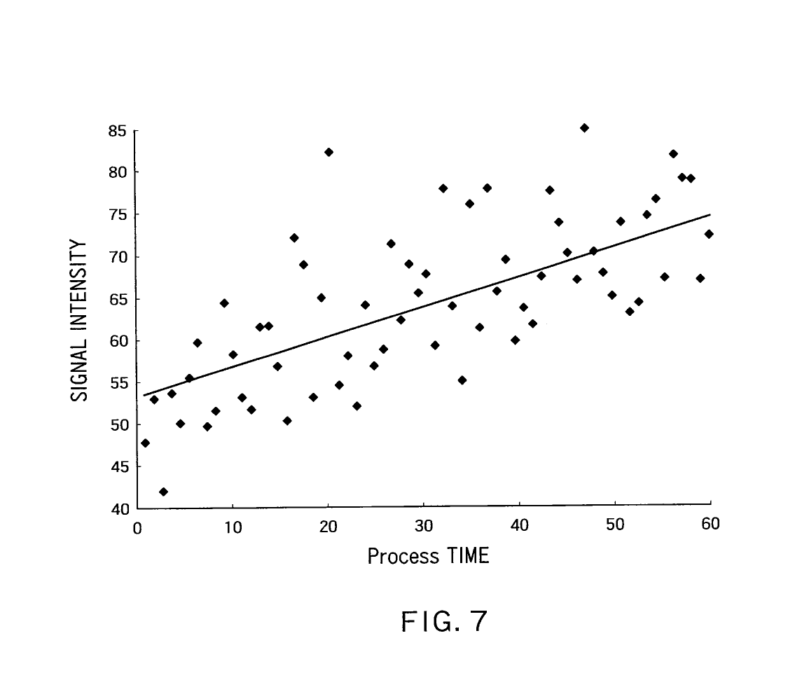

The film thickness monitoring method according to a reference example will now be described with reference to FIG. 6A to FIG. 7.

As shown in FIG. 6A, in this reference example, continuous scan is simply effected during relative rotation of the polishing pad 12 and the wafer W in FIG. 1, reflected light is detected, and a film thickness is calculated from intensity of this light. Since the light is allowed to continuously illuminate the wafer W and the reflected light is detected from the start to the end of the polishing, the trajectory of the film thickness monitoring device 30 in a shot in the processing is as shown in, e.g., FIG. 6B.

Therefore, the signal intensity of the reflected light takes such a distribution as shown in FIG. 7 with progress of a polishing time. As obvious from comparison with FIG. 5, in this reference example, since the light is allowed to illuminate the wafer W and the reflected light is detected on both the memory cell region Rc and the dicing region Rd, signals from the ROI and signals from regions other than the ROI are mixed, and calculating the film thickness with a sufficient accuracy is difficult.

On the other hand, according to this example, since an intensity signal of the reflected light from the ROI is selectively obtained, the film thickness can be highly accurately monitored.

In the above description, the passage time zone is estimated in advance and the reflected light is detected in the obtained passage time zone alone, but the embodiment is not restricted thereto, the reflected light may be detected from the entire trajectory Tall, its intensity data may be temporarily obtained, and data other than the passage time zone may be eliminated from the obtained intensity data and then processed, whereby the film thickness of the interlayer insulating film 210 is calculated.

### (2) Example 2

When a three-dimensional shape or a material of a pattern changes on the wafer W which the light illuminates during progress of monitoring scan, the intensity of the reflected light from the wafer W also varies in accordance with this change. For example, again referring to FIG. 3, when memory devices are repeatedly formed in an array shape on the wafer W and a laminated structure if formed, it is assumed that there is a case in which reflected light intensity from each memory cell region Rc may be lower than reflected light intensity from each dicing region Rd and the reflected light intensity from the dicing region Rd may be higher than the reflected light intensity from the memory cell region Rc.

In this case, if the reflected light intensity has precipitously increased during the continuous scan, it can be determined that the monitoring scan position has moved from the memory cell region Rc to the dicing region Rd. Contrarily, if the reflected light intensity has precipitously decreased during the continuous scan, it can be determined that the monitoring scan position has moved from the dicing region Rd to the memory cell region Rc. Thus, when a fluctuation in reflected light intensity is associated with a polishing time, and a time interval associated with reflected light in a period from a drastic drop to a precipitous rise of intensity is selected from respective reflected lights having relatively small fluctuation amounts, a time zone in which the light passes the memory cell region Rc can be identified.

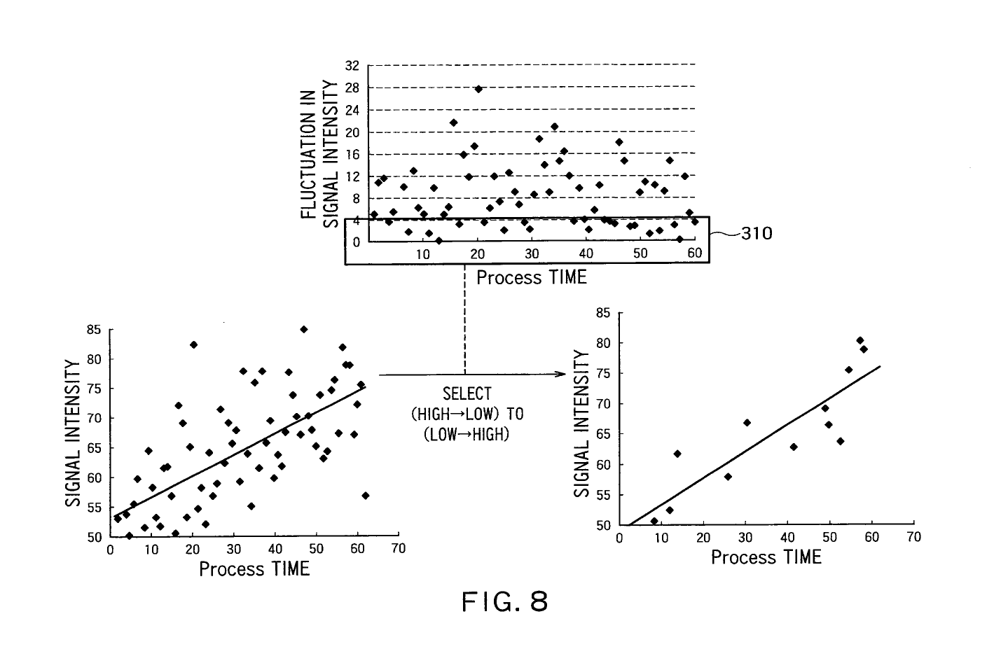

More specifically, for example, like the above-described water polishing, the monitoring scan prior to the polishing process is continuously carried out, the light detector 33 detects the reflected light intensity in regard to the overall trajectory Tall (see FIG. 6A), and a detection signal is supplied to the passage time identifying section 35 in FIG. 2. A lower left side in FIG. 8 shows an example of a relationship between intensity of the obtained detection signal and a process time.

The passage time identifying section 35 in FIG. 2 associates the detection signal with progress of the polishing time and then calculates a fluctuation in signal intensity at preset time intervals. An upper side in FIG. 8 shows an example of a relationship between the calculated fluctuation in signal intensity and a process time.

The passage time identifying section 35 in FIG. 2 fetches signal intensity fluctuations belonging to a range where a fluctuation amount is relatively small, e.g., a range of 0 to 4 in the example shown on the upper side in FIG. 8 from the calculated signal intensity fluctuations. The passage time identifying section 35 further selects fluctuations in a period from a drastic fall to a precipitous rise of the signal intensity from the signal intensity fluctuations, connects time intervals corresponding to the respective selected fluctuations, and estimates the connected time interval as a time zone in which the light passes the memory cell region Rc.

When polishing the wafer W starts under control of the control section 100 in FIG. 2, the film thickness monitoring device 30 allows the light to illuminate the wafer W concurrently with the polishing process in accordance with data of the passage time zone estimated by the passage time identifying section 35, detects reflected light by using the light detector 33, outputs a signal indicative of reflection intensity of the reflected light, and calculates the film thickness of the interlayer insulating film 210 in FIG. 3 by using the film thickness calculating section 37.

In the above description, the passage time zone is estimated in advance and the reflected light is detected in the obtained passage time zone alone in the actual polishing process, but the present embodiment is not restricted thereto, the reflected light may be detected in regard to the overall trajectory Tall, and its intensity data may be acquired, and data other than the passage time zone may be eliminated from the obtained intensity data, and then processing may be carried out, thereby calculating the film thickness of the interlayer insulating film 210.

Moreover, in the above example, a description has been given as to the case where the reflected light intensity from each memory cell region Rc in FIG. 3 is lower than the reflected light intensity from each dicing region Rd and the reflected light intensity from each dicing region Rd is higher than the reflected light intensity from each memory cell region Rc. However, since a phase of the light from each interface changes in accordance with each material/film thickness of the laminated structure including the uppermost layer which is the processing target, there may be an opposite example, namely, the reflected light intensity from each memory cell region Rc may be higher than the reflected light intensity from each dicing region Rd and the reflected light intensity from the dicing region Rd may be lower than the reflected light intensity from the memory cell region Rc, and a way of selecting time interval is appropriately changed in accordance with each processing target.

The lower right side in FIG. 8 shows an example of a distribution of the signal intensity of the reflected light detected only in the passage time zone which is estimated in this example. It can be understood from this drawing that the signal intensity tends to gradually increase with progress of the polishing process.

According to the film thickness monitoring device of at least one of the foregoing embodiments, since an intensity signal of reflected light from a desired region on the wafer is selectively acquired and a film thickness is calculated, the film thickness can be highly accurately monitored.

Further, according to the film thickness monitoring method of at least one of the foregoing examples, since an intensity signal of reflected light from a desired region on the wafer is selectively acquired and a film thickness is calculated, the film thickness can be highly accurately monitored.

(B) Semiconductor Manufacturing Apparatus according to

### Embodiment 2

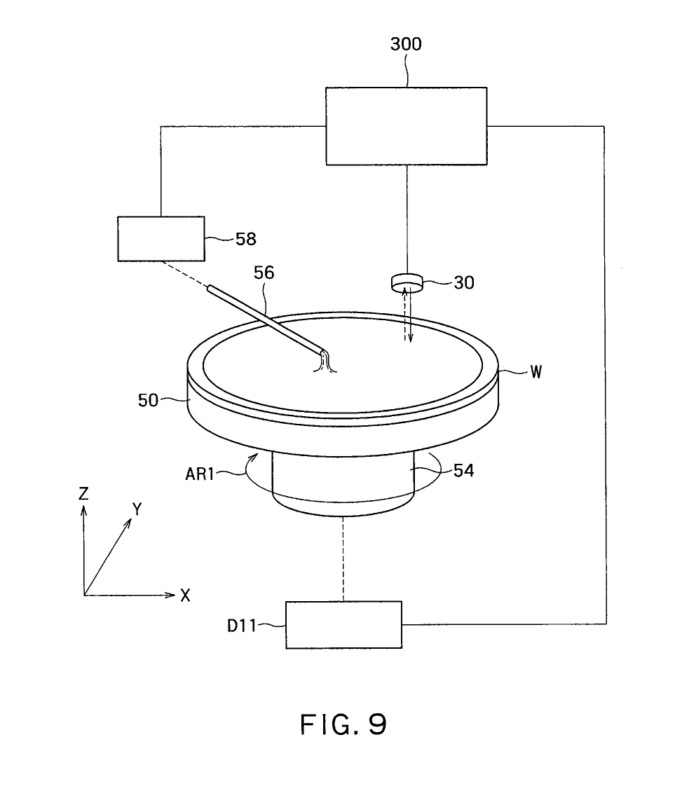

FIG. 9 is a view showing an outline configuration of a semiconductor manufacturing apparatus according to Embodiment 2. The semiconductor manufacturing apparatus shown in FIG. 9 is a film forming apparatus including a wafer table 50, a wafer table shaft 54, a nozzle 56, a film forming material supply mechanism 58, a control section 300, and a film thickness monitoring device 30.

The wafer table 50 is coupled with the wafer table shaft 54 and supports a wafer W on an upper surface thereof or the like. The wafer table 50 rotates in a rotating direction indicated by, e.g., a reference sign AR1 in FIG. 9 when the wafer table shaft 54 rotates by a drive mechanism D11 including a motor (not shown) and others. In this embodiment, the wafer table 50 corresponds to, e.g., a first table.

It is to be noted that the wafer table shaft 54 and the wafer table 50 can not only rotate but also move in three-dimensional arbitrary directions, i.e., all of an X direction, a Y direction, and a Z direction in FIG. 9, thereby enabling scanning by the film thickness monitoring device 30 based on an arbitrary procedure.

The film forming material supply mechanism 58 supplies a film forming material such as a resist material onto the wafer W through the nozzle 56. The film forming material supplied to the upper side of the wafer W spreads from the center toward the periphery on the upper surface of the wafer W when the wafer W rotates by rotation of the wafer table 50, whereby a film thickness is averaged.

The film thickness monitoring device 30 measures a thickness of the film during film formation, calculates a film forming amount, and supplies data of the calculated film thickness to the control section 300.

The control section 300 generates respective control signals, supplies them to the drive mechanism D11, the film forming material supply mechanism 58, and the film thickness monitoring device 30, and controls a general film forming process while monitoring the film forming amount. When the film thickness calculated by the film thickness monitoring device 30 reaches a desired value, the control section 300 terminates the film forming process.

A configuration and an operation of the film thickness monitoring device 30 provided in the film forming apparatus and the film thickness monitoring method according to this embodiment are substantially equal to the contents explained in regard to the film thickness monitoring device provided in the polishing apparatus according to Embodiment 1 except that scanning effected in advance does not require supply of other liquids such as pure water, and hence a detailed description thereof will be omitted.

According to at least one of the semiconductor manufacturing apparatuses described above, the apparatus includes the film thickness monitoring device, and hence the manufacturing process can be performed without excess or deficiency, and a yield ratio and throughput in manufacture of a semiconductor device can be improved. While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the sprit of the inventions. The accompanying claims and their equivalents are intended to cover such forms or modifications as would fall within the scope and spirit of the inventions.

1. A film thickness monitoring method comprising:
applying light to a substrate, which is a processing target, in a semiconductor manufacturing process involving rotation of the substrate;
detecting reflected light from the substrate; and
identifying a time zone in which incident light passes a desired region on the substrate during the semiconductor manufacturing process, and calculating a thickness of a film on the substrate from intensity of the reflected light detected in the identified time zone.

2. The method of claim 1,
wherein the time zone is previously identified before processing relative to the substrate, and
the thickness of the film is monitored from the intensity of the reflected light detected in the identified time zone during an actual semiconductor manufacturing process.

3. The method of claim 1,
wherein identifying the time zone comprises:
scanning the substrate by using the incident light, and acquiring coordinate information which corresponds to a trajectory of the incident light in association with information of a manufacturing time; and
checking the coordinate information by comparing it with a design layout of an element to be formed on the substrate.

4. The method of claim 3,
wherein cells are formed on the substrate at predetermined intervals, and
the desired region is a region which is apart from the center of the cells by a predetermined distance.

5. The method of claim 1,
wherein identifying the time zone comprises:
using design data of an apparatus adopted in the semiconductor manufacturing process, and acquiring coordinate information which corresponds to a trajectory of the incident light in association with a process time for the substrate; and
checking the coordinate information by comparing it with a design layout of an element to be formed on the substrate.

6. The method of claim 1,
wherein light is emitted and applied to the substrate, reflected light from the substrate is detected before processing relative to the substrate, and the time zone is identified from a temporal fluctuation in intensity of the detected reflected light.

7. The method of claim 1,
wherein the time zone is identified from a temporal fluctuation in intensity of reflected light which is detected by irradiating the substrate with light in an actual semiconductor manufacturing process, and
the film thickness is monitored from the intensity of the reflected light alone in the identified time zone.

8. A film thickness monitoring device comprising:
a light irradiating section configured to emit light and apply the light to a rotating substrate;
a detecting section configured to detect reflected light from the substrate;
a passage time identifying section configured to identify a time zone in which incident light passes a desired region on the substrate; and
a calculating section configured to calculate a thickness of a film on the substrate from intensity of the reflected light detected in the identified time zone.

9. The device of claim 8,
wherein the passage time identifying section previously identifies the time zone before processing for the substrate, and
the calculating section calculates the film thickness from intensity of the reflected light detected in the identified time zone during an actual semiconductor manufacturing process.

10. The device of claim 8,
wherein the passage time identifying section identifies the time zone by acquiring coordinate information, which is used as a trajectory of the incident light, through scan on the substrate by using the incident light in association with information of a manufacturing time and checking the acquired coordinate information by comparing it with a design layout of an element to be formed on the substrate.

11. The device of claim 10,
wherein cells are formed on the substrate at predetermined intervals, and
the desired region is a region which is apart from the center of the cells by a predetermined distance.

12. The device of claim 8,
wherein the passage time identifying section identifies the time zone by acquiring coordinate information, which is used as a trajectory of the incident light, with use of design data of an external device adopted in the semiconductor manufacturing process in association with a process time for the substrate and checking the acquired coordinate information by comparing it with a design layout of an element to be formed on the substrate.

13. The device of claim 8,
wherein the light irradiating section irradiates the substrate with light before processing for the substrate, and
the passage time identifying section identifies the time zone from a temporal fluctuation in intensity of the reflected light detected by the detecting section.

14. The device of claim 8,
wherein the light irradiating section irradiates the substrate with light in an actual semiconductor manufacturing process,
the passage time identifying section identifies the time zone from a temporal fluctuation in intensity of the reflected light detected by the detecting section, and
the calculating section calculates the film thickness from the intensity of the reflected light alone in the identified time zone.

15. A semiconductor manufacturing apparatus comprising:
a first table configured to hold and rotate a substrate; and
a film thickness monitor configured to monitor a thickness of a film on the substrate,
the film thickness monitor comprising:
a light irradiating section configured to emit light and apply the light to the rotating substrate;
a detecting section configured to detect reflected light from the substrate;
a passage time identifying section configured to identify a time zone in which incident light passes a desired region on the substrate; and
a calculating section configured to calculate the thickness of the film on the substrate from intensity of the reflected light detected in the identified time zone.

16. The semiconductor manufacturing apparatus of claim 15, further comprising:
a polishing pad; and
a second table configured to support the polishing pad,
wherein the first table is a top ring that presses the substrate against the polishing pad.

17. The semiconductor manufacturing apparatus of claim 15, further comprising a supply section which supplies a film material to the substrate,
wherein the film thickness monitor monitors the thickness of the film that is formed on the substrate.
